(19) United States
(12) Patent Application Publication
(10) Pub. No.: US 2025/0393484 A1
(43) Pub. Date: Dec. 25, 2025

(54) SEMICONDUCTOR DEVICE INCLUDING QUANTUM DOTS AND MANUFACTURING METHOD

(71) Applicant: SK hynix Inc., Icheon-si, Gyeonggi-do (KR)

(72) Inventors: Hwan Young KIM, Icheon-si, Gyeonggi-do (KR); Won Tae KOO, Icheon-si, Gyeonggi-do (KR)

(73) Assignee: SK hynix Inc., Icheon-si, Gyeonggi-do (KR)

(21) Appl. No.: 18/824,501

(22) Filed: Sep. 4, 2024

(30) Foreign Application Priority Data
Jun. 25, 2024 (KR) 10-2024-0082532

(51) Int. Cl. H10N 70/20; H10B 63/00; H10N 70/00

(52) U.S. Cl. CPC H10N 70/24; H10B 63/20; H10N 70/8416; H10N 70/8833; H10N 70/25

(57) ABSTRACT

A semiconductor device may include: a first electrode; a switching layer located on the first electrode; an oxygen reservoir layer located on the switching layer; a second electrode located on the oxygen reservoir layer; and a quantum dot located between the first electrode and the switching layer.

### CROSS-REFERENCE TO RELATED APPLICATION

This application claims priority under 35 U.S.C. § 119 to Korean Patent Application No. 10-2024-0082532, filed on Jun. 25, 2024 in the Korean Intellectual Property Office, which is incorporated herein by reference in its entirety.

### BACKGROUND

### 1. Technical Field

Embodiments of the present disclosure relate to an electronic device, and more particularly, to a semiconductor device and a method of manufacturing the semiconductor device.

### 2. Related Art

Recently, in accordance with miniaturization, low power consumption, performance improvement, diversification, and the like, of electronic devices, semiconductor devices capable of storing information have been demanded in various electronic devices such as computers and portable communication devices. In particular, an interest in neuromorphic technology that imitates the human nervous system has increased. The human nervous system includes hundreds of billions of neurons and synapses, which are junctions between the neurons. In the neuromorphic technology, designing neuron circuits and synapse circuits corresponding to such neurons and synapses is intended to be implemented with semiconductor devices. Semiconductor devices used in implementing the neuromorphic technology may be utilized in various fields such as data classification and pattern recognition.

### SUMMARY

In an embodiment, a semiconductor device may include: a first electrode; a switching layer on the first electrode; an oxygen reservoir layer on the switching layer; a second electrode on the oxygen reservoir layer; and a quantum dot between the first electrode and the switching layer.

In an embodiment, a semiconductor device may include: a first electrode; a first switching layer located on the first electrode; a second switching layer located on the first switching layer; an oxygen reservoir layer located on the second switching layer; a second electrode located on the oxygen reservoir layer; and a quantum dot located between the first switching layer and the second switching layer.

In an embodiment, a manufacturing method of a semiconductor device may include: forming a first electrode; forming a quantum dot on the first electrode; forming a switching layer on the first electrode on which the quantum dot is formed; forming an oxygen reservoir layer on the switching layer; and forming a second electrode on the oxygen reservoir layer.

In an embodiment, a manufacturing method of a semiconductor device may include: forming a first electrode; forming a first switching layer on the first electrode; forming a quantum dot on the first switching layer; forming a second switching layer on the first switching layer on which the quantum dot is formed; forming an oxygen reservoir layer on the second switching layer; and forming a second electrode on the oxygen reservoir layer.

### BRIEF DESCRIPTION OF THE DRAWINGS

FIG. 1 is a diagram describing a semiconductor device in accordance with an embodiment of the disclosure.

FIG. 2 is a diagram illustrating a configuration of a semiconductor device in accordance with an embodiment of the disclosure.

FIG. 3 is a diagram illustrating a configuration of a semiconductor device in accordance with an embodiment of the disclosure.

FIG. 4 is a diagram illustrating a configuration of a semiconductor device in accordance with an embodiment of the disclosure.

FIGS. 5A to 5D are diagrams describing operations of resistive memory cells in accordance with embodiments of the disclosure.

FIG. 6 is a graph illustrating characteristics of a semiconductor device in accordance with an embodiment of the disclosure.

FIGS. 7A and 7B are diagrams describing a manufacturing method of a semiconductor device in accordance with an embodiment of the disclosure.

FIGS. 8A and 8B are diagrams describing a manufacturing method of a semiconductor device in accordance with an embodiment of the disclosure.

FIGS. 9A and 9B are diagrams describing a manufacturing method of a semiconductor device in accordance with an embodiment of the disclosure.

### DETAILED DESCRIPTION

Various embodiments are directed to semiconductor devices having a stable structure and improved characteristics and methods of manufacturing the semiconductor devices.

With the disclosed invention, it is possible to improve the linearity of synaptic cells and improve the operation characteristics of a neuromorphic device.

Hereafter, embodiments in accordance with the technical spirit of the present disclosure will be described with reference to the accompanying drawings.

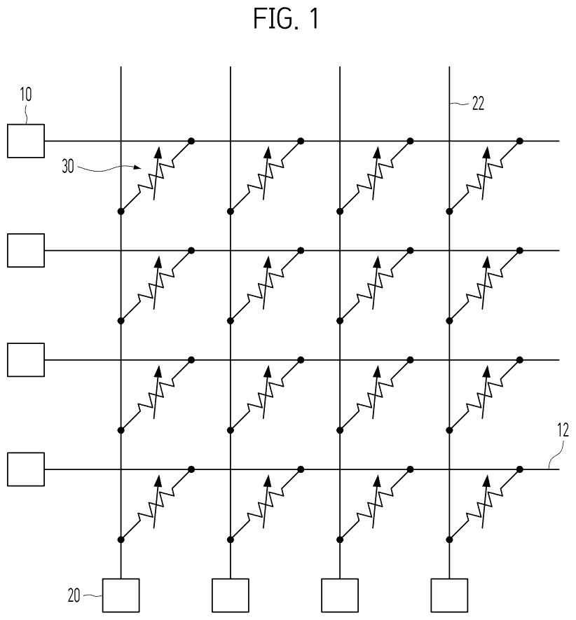

FIG. 1 is a diagram describing a semiconductor device in accordance with an embodiment of the disclosure.

Referring to FIG. 1, a semiconductor device may be a neuromorphic device, and may include a plurality of pre-synaptic neurons 10, a plurality of post-synaptic neurons 20, and synaptic cells 30.

The semiconductor device may further include row lines 12 and column lines 22. A pre-synaptic neuron 10 and a synaptic cell 30 may be connected to each other through a row line 12, and a post-synaptic neuron 20 and a synaptic cell 30 may be connected to each other through a column line 22. The row line 12 may correspond to an axon of the pre-synaptic neuron 10, and the column line 22 may correspond to a dendrite of the post-synaptic neuron 20.

A synaptic cell 30 may be disposed at each of the intersection points between the row lines 12 and the column lines 22. A synaptic cell 30 may be connected between a pre-synaptic neuron 10 and a post-synaptic neuron 20 through a row line 12 and a column line 22.

The pre-synaptic neuron 10 may generate a signal corresponding to specific data and transmit the generated signal to the row line 12. The post-synaptic neuron 20 may receive and process a synaptic signal that has passed through the synaptic cell 30, via the column line 22. The pre-synaptic neuron 10 and the post-synaptic neuron 20 may be implemented with various circuits such as complementary metal oxide semiconductors (CMOSs), as a non-limiting example.

The synaptic cell 30 is an element whose electrical conductance or weight changes depending on an electrical pulse such as a voltage or a current applied to both of its ends. As an example, the synaptic cell 30 may be a variable resistance element or a resistive memory cell. The variable resistance element may switch between different resistance states depending on a voltage or a current applied to both of its ends. The variable resistance element may include a switching layer that may have multi-level resistance states. The switching layer may be a resistive switching layer. For example, the switching layer may include metal oxide such as transition metal oxide and a perovskite-based material, a phase change material such as a chalcogenide-based material, a ferroelectric material, a ferromagnetic material, and the like.

The synaptic cell 30 may change from a high-resistance state to a low-resistance state through a set operation, and may change from a low-resistance state to a high-resistance state through a reset operation. A weight for a synaptic state may be stored in the synaptic cell 30 through the set/reset operation. In order to store an accurate weight, the synaptic cell 30 may have analog characteristics in that resistance changes in proportion to an applied voltage without undergoing an abrupt change in resistance during the set/reset operation. Through such analog characteristics, conductance (i.e., the weight of the synaptic cell 30) may be changed, and matrix multiplication operation, which is a process of multiplying an external input voltage by the weight, may be performed.

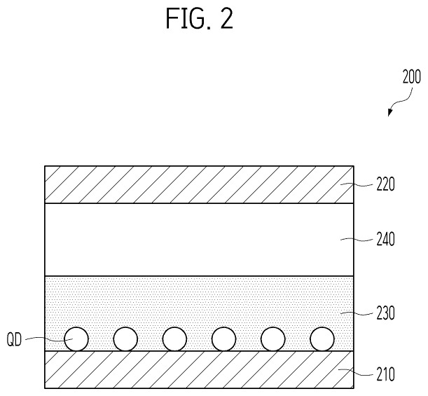

FIG. 2 is a diagram illustrating a configuration of a semiconductor device in accordance with an embodiment of the disclosure. Hereinafter, content that overlaps with previously described content may be omitted from the description for clarity.

Referring to FIG. 2, a resistive memory cell 200 may include a first electrode 210, a second electrode 220, a switching layer 230, an oxygen reservoir layer 240, and quantum dots QD. The switching layer 230 may be located on the first electrode 210, the oxygen reservoir layer 240 may be located on the switching layer 230, and the second electrode 220 may be located on the oxygen reservoir layer 240.

The first electrode 210 and the second electrode 220 may each include a conductive material such as polysilicon or metal. As non-limiting examples, the first electrode 210 and the second electrode 220 may each include polysilicon, tungsten (W), tungsten nitride (WNₓ), tungsten silicide (WSiₓ), titanium (Ti), titanium nitride (TiNₓ), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SIC), silicon carbonitride (SiCN), copper (Cu), zinc (Zn), nickel (Ni), cobalt (Co), lead (Pb), platinum (Pt), molybdenum (Mo), ruthenium (Ru), or the like, or include combinations thereof. The first electrode 210 and the second electrode 220 may include the same material or different materials. As an example, the first electrode 210 and the second electrode 220 may each include a titanium nitride layer.

The switching layer 230 may have variable resistance characteristics in which the switching layer exhibits different resistance states depending on a voltage or a current supplied through the first electrode 210 and the second electrode 220. As an example, the resistance of the switching layer 230 may change by the alternating generation and dissipation of internal conductive filaments. The filament electrically connects the first electrode 210 and the second electrode 220 to each other, and may be generated, partially generated, or may dissipate according to the movement of oxygen vacancies. Here, the oxygen vacancy may be a lattice defect occurring when oxygen escapes from a location to which oxygen should be bonded. The oxygen vacancy may exhibit the same behavior as a particle having a positive charge, such as a hole. When the oxygen vacancies are connected to each other, a filament may be generated, and when the oxygen vacancies are disconnected from each other, the filament may disappear. The switching layer 230 may include metal oxide, and metal included in the switching layer 230 may be transition metal. As an example, the switching layer 230 may include metal such as Al, Si, Ti, Cr, Mn, Ni, Cu, Zn, Y, Zr, Nb, Hf, Ta, or W. The switching layer 230 may include HfO₂, TiO₂, Al₂O₃, ZrO₂, ZnO, or the like.

The oxygen reservoir layer 240 may include or reserve the oxygen vacancies necessary for the generation of the filament and may receive oxygen vacancies. During resistance switching driving of the resistive memory cell 200, oxygen ions and/or the oxygen vacancies may be exchanged between the switching layer 230 and the oxygen reservoir layer 240. As an example, during a set operation, a filament may be generated in the switching layer 230 by the oxygen vacancies supplied from the oxygen reservoir layer 240, and resistance of the switching layer 230 may decrease as a result. During a reset operation, the oxygen vacancies of the filament may be transferred to the oxygen reservoir layer 240, such that the filament may dissipate and the resistance of the switching layer 230 may increase. The oxygen reservoir layer 240 may include metal or metal oxide. As an example, the oxygen reservoir layer 240 may include metal such as Ti, Ta, or Hf.

The quantum dots QD may be nano-sized particles and may each have a dot or dot-like shape. The quantum dots QD may have quantum mechanical properties such as discrete energy states. The quantum dots QD may be located between the first electrode 210 and the switching layer 230, and may be located at or near an interface between the first electrode 210 and the switching layer 230. The quantum dots QD may be spaced apart from each other, and the switching layer 230 may be filled between adjacent quantum dots QD. The quantum dots QD may include a metal-based material or an oxide-based material. As an example, the quantum dots QD may each be a metal-based material, an oxide-based material, or a metal-based material coated with an oxide-based material.

According to the structure described above, a resistive memory cell 200 may include the quantum dots QD. An electric field may be concentrated locally at locations using the quantum dots QD, and the filaments may be uniformly formed in the switching layer 230 during a set operation.

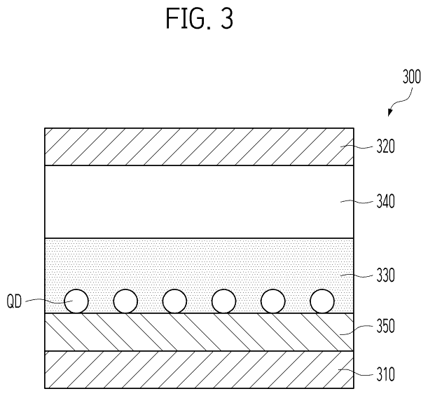

FIG. 3 is a diagram illustrating a configuration of a semiconductor device in accordance with an embodiment of the disclosure. Hereinafter, content that overlaps with previously described content may be omitted for clarity.

Referring to FIG. 3, a resistive memory cell 300 may include a first electrode 310, a second electrode 320, a switching layer 330, an oxygen reservoir layer 340, a seed layer 350, and quantum dots QD. The seed layer 350 may be located on the first electrode 310, the switching layer 330 may be located on the seed layer 350, the oxygen reservoir layer 340 may be located on the switching layer 330, and the second electrode 320 may be located on the oxygen reservoir layer 340.

The seed layer 350 may be a layer used as a seed for forming the quantum dots QD in a manufacturing process. The seed layer 350 may include metal such as titanium (Ti), gold (Au), or platinum (Pt), or include a two-dimensional material. As an example, the two-dimensional material may include noble metal. The seed layer 350 may include a conductive material and may be used as an electrode together with the first electrode 310.

The quantum dots QD may be located between the seed layer 350 and the oxygen reservoir layer 340. The quantum dots QD may be located between the seed layer 350 and the switching layer 330, and may be located at or near an interface between the seed layer 350 and the switching layer 330. The quantum dots QD may be spaced apart from each other, and the switching layer 330 may be filled between adjacent quantum dots QD. The quantum dots QD may each be a metal-based material, an oxide-based material, or a metal-based material coated with an oxide-based material.

According to the structure described above, a resistive memory cell 300 may include the quantum dots QD. An electric field may be concentrated at locations local to the quantum dots QD, and the filaments may be uniformly formed in the switching layer 330 during the set operation.

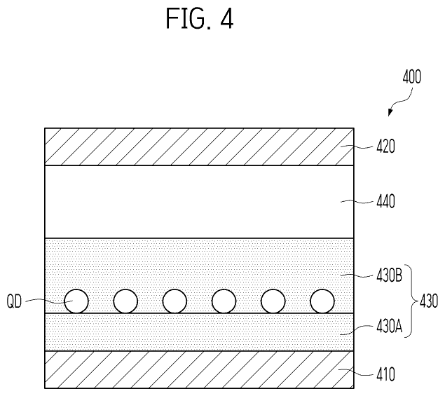

FIG. 4 is a diagram illustrating a configuration of a semiconductor device in accordance with an embodiment of the disclosure. Hereinafter, content that overlaps with previously described content may be omitted from the description for clarity.

Referring to FIG. 4, a resistive memory cell 400 may include a first electrode 410, a second electrode 420, a switching layer 430, an oxygen reservoir layer 440, and quantum dots QD. The switching layer 430 may be located on the first electrode 410, the oxygen reservoir layer 440 may be located on the switching layer 430, and the second electrode 420 may be located on the oxygen reservoir layer 440.

The switching layer 430 may include a first switching layer 430A and a second switching layer 430B. The second switching layer 430B may be located on the first switching layer 430A. Sizes, compositions, and the like, of the first switching layer 430A and the second switching layer 430B may be adjusted in consideration of operation characteristics of the resistive memory cell 400. As an example, the first switching layer 430A and the second switching layer 430B may have different thicknesses, and the second switching layer 430B may have a greater thickness than the first switching layer 430A.

The quantum dots QD may be located inside the switching layer 430. As an example, the quantum dots QD may be located between the first switching layer 430A and the second switching layer 430B, and may be located at or near an interface between the first switching layer 430A and the second switching layer 430B. As an example, the second switching layer 430B may have the greater thickness than the first switching layer 430A, and the quantum dots QD may be located closer to the first electrode 410 than the oxygen reservoir layer 440. The quantum dots QD may be spaced apart from each other, and the second switching layer 430B may be filled between adjacent quantum dots QD. The quantum dots QD may each be a metal-based material, an oxide-based material, or a metal-based material coated with an oxide-based material.

According to the structure described above, a resistive memory cell 400 may include the quantum dots QD. An electric field may be concentrated locally at locations at or near the quantum dots QD, and the filaments may be uniformly formed in the switching layer 430 during a set operation.

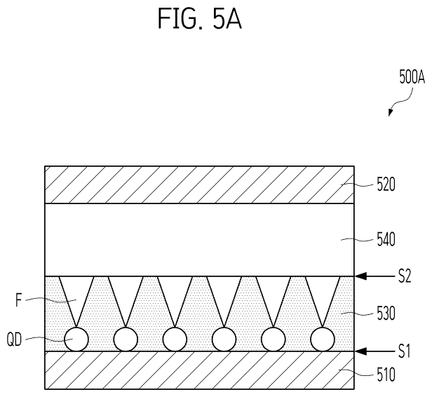

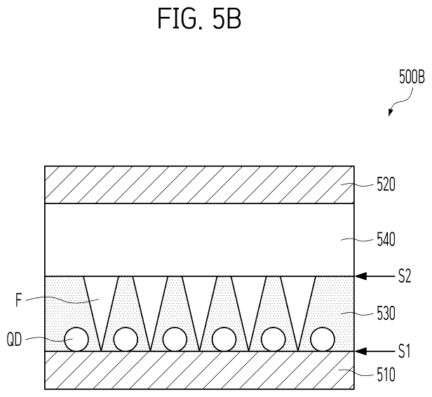

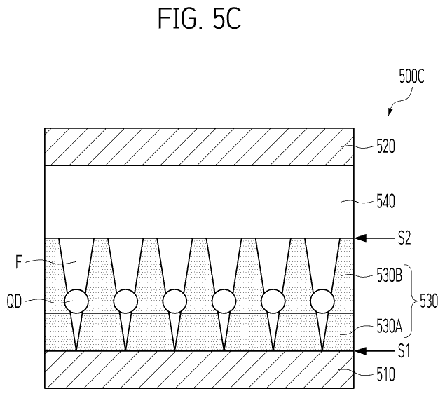

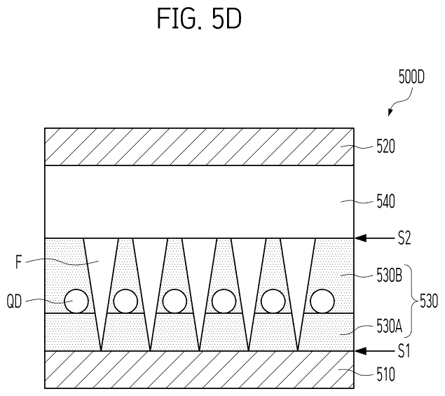

FIGS. 5A to 5D are diagrams describing operations of resistive memory cells in accordance with embodiments of the disclosure. Hereinafter, content that overlaps with previously described content may be omitted from the description for clarity.

Referring to FIG. 5A, a resistive memory cell 500A may include a first electrode 510, a second electrode 520, a switching layer 530, an oxygen reservoir layer 540, and quantum dots QD. The switching layer 530 may include a first surface S1 facing or common to the first electrode 510 and a second surface S2 facing or common to the oxygen reservoir layer 540, and the quantum dots QD may be located on the first surface S1. The quantum dots QD may be electrically connected to the first electrode 510, and may serve as an electrode together with the first electrode 510. The quantum dots QD may each be a metal-based material. As an example, the quantum dots QD may each include titanium (Ti), gold (Au), platinum (Pt), or the like, or include noble metal.

During a set operation, filaments F may grow from the second surface S2 toward the first surface S1, and the growth of the filaments F within the switching layer 530 may be promoted or facilitated by the quantum dots QD. The quantum dots QD may include a metal-based material. When the quantum dots QD are formed of metal-based materials, a work function of the quantum dots QD is lower than a charge neutrality level of the switching layer 530, and thus, electrons may be trapped at interfaces between the quantum dots QD and the switching layer 530. Accordingly, during the set operation, an electric field may be concentrated on the quantum dots QD, and the filaments F growing toward the first surface S1 may reach the quantum dots QD. The switching layer 530 on which the set operation is performed may include filaments F between and connecting the second surface S2 and the quantum dots QD. Because the filaments F grow toward and contact the quantum dots QD, the filaments F may be induced to grow uniformly rather than randomly towards the first electrode 510. The filaments F may be uniformly distributed in the switching layer 530 with the quantum dots QD, on which the electric field are concentrated. As a result, random arrangements of electronic channels may be avoided, and the distribution of set/reset states may be improved.

A resistance state of the resistive memory cell 500A may be finely adjusted to a multi-level state using the quantum dots QD. The filaments F may be grown efficiently through the concentrated electric field effects, and resistance of the resistive memory cell 500A may be changed in proportion to an applied voltage. Accordingly, the resistive memory cell 500A may have analog characteristics, and may have improved linearity.

Power consumption of the resistive memory cell 500A may be reduced through the quantum dots QD. Because the quantum dots QD have high electron affinity, electrons may be trapped at the interfaces between the quantum dots QD and the switching layer 530. Accordingly, a level of a voltage required to turn on the resistive memory cell 500A may be reduced.

A negative set phenomenon of the resistive memory cell 500A may be improved through the quantum dots QD. During a reset operation, oxygen vacancies are disconnected from each other, such that the filaments dissipate or are disconnected. Oxygen vacancies, however, may be supplied from the first electrode 510 to prevent or slow the degradation of the filaments. According to this negative set phenomenon, the oxygen vacancies diffuse from the first electrode 510 to the switching layer 530, such that the filaments may be connected to the first electrode 510, and the resistive memory cell 500A has a set state rather than a reset state. According to an embodiment of the present disclosure, the quantum dots QD are located at an interface between the first electrode 510 and the switching layer 530, and thus, oxygen vacancies can diffuse through the quantum dots QD. When the quantum dots QD do not exist, the oxygen vacancies diffuse through a grain boundary of the first electrode 510, and thus, diffusion barriers are relatively low, but when the quantum dots QD exist, the oxygen vacancies diffuse through the inside of the quantum dots QD by vacancy diffusion, and thus, the diffusion barriers are relatively high. Accordingly, the oxygen vacancies do not diffuse but remain inside the quantum dots QD, and the quantum dots QD may serve as diffusion barriers for the oxygen vacancies.

Referring to FIG. 5B, a resistive memory cell 500B may include a first electrode 510, a second electrode 520, a switching layer 530, an oxygen reservoir layer 540, and quantum dots QD. The switching layer 530 may include a first surface S1 facing or common to the first electrode 510 and a second surface S2 facing or common to the oxygen reservoir layer 540, and the quantum dots QD may be located on the first surface S1. The quantum dots QD may each be an oxide-based material or a metal-based material coated with an oxide-based material. As an example, the quantum dots QD may each include an oxide-based material such as SiO₂, Al₂O₃, La₂O₃, Gd₂O₃, and ZrO₂.

During a set operation, filaments F may grow from the second surface S2 toward the first surface S1, and the growth of the filaments F within the switching layer 530 may be promoted by the quantum dots QD. The quantum dots QD may include an oxide-based material. When the quantum dots QD are formed of oxide-based materials, an energy level of a conductive band of the quantum dots QD is higher than that of the switching layer 530. Therefore, the quantum dots QD have lower electron affinity than the switching layer 530, and an electric field does not concentrate on the quantum dots QD. Instead, an electric field applied to the switching layer 530 is concentrated on portions of the first surface S1 where the quantum dots QD do not exist at an interface between the switching layer 530 and the first electrode 510, and the filaments F may reach the first surface S1 while avoiding the quantum dots QD. The switching layer 530 on which the set operation is performed may include filaments F between and connecting the second surface S2 and the first surface S1 without contacting the quantum dots QD. By concentrating the electric field on portions of the first surface S1 that avoid the quantum dots QD as described above, it is possible to uniformly grow the filaments F that do not contact the quantum dots QD. The filaments F may be uniformly distributed in the switching layer 530 under an electric field while avoiding the quantum dots QD.

Referring to FIG. 5C, a resistive memory cell 500C may include a first electrode 510, a second electrode 520, a switching layer 530, an oxygen reservoir layer 540, and quantum dots QD. The switching layer 530 may include a first switching layer 530A and a second switching layer 530B. The first switching layer 530A may include a first surface S1 facing or common to the first electrode 510, and the second switching layer 530B may include a second surface S2 facing or common to the oxygen reservoir layer 540.

The quantum dots QD may be located at an interface between the first switching layer 530A and the second switching layer 530B. As an example, the quantum dots QD may each include a metal-based material. The quantum dots QD may each include titanium (Ti), gold (Au), platinum (Pt), or the like, or include noble metals.

During a set operation, the growth of filaments F within the switching layer 530 may be promoted or facilitated by the quantum dots QD. The filaments F may grow from the second surface S2 towards the first surface S1 through the quantum dots QD. The filaments F may grow toward the quantum dots QD within the second switching layer 530B, and may grow from the quantum dots QD within the first switching layer 530A to the first surface S1. Accordingly, the filaments F may be uniformly grown and distributed in the switching layer 530. The switching layer 530 on which the set operation is performed may include filaments F connected between the second surface S2 and the first surface S1 through the quantum dots QD. The filaments F may be uniformly distributed in the switching layer 530 by an electric field that is concentrated on the quantum dots QD.

Referring to FIG. 5D, a resistive memory cell 500D may include a first electrode 510, a second electrode 520, a switching layer 530, an oxygen reservoir layer 540, and quantum dots QD. The switching layer 530 may include a first switching layer 530A and a second switching layer 530B. The first switching layer 530A may include a first surface S1 facing or common to the first electrode 510, and the second switching layer 530B may include a second surface S2 facing or common to the oxygen reservoir layer 540.

The quantum dots QD may be located at an interface between the first switching layer 530A and the second switching layer 530B. As an example, the quantum dots QD may each include an oxide-based material or a metal-based material coated with an oxide-based material. In other examples, the quantum dots QD may each include an oxide-based material such as SiO₂, Al₂O₃, La₂O₃, Gd₂O₃, and ZrO₂. The quantum dots QD may each be a graphite oxide quantum dot as a further example.

During a set operation, the growth of filaments F within the switching layer 530 may be promoted or facilitated by the presence of the quantum dots QD. The filaments F may grow from the second surface S2 to the first surface S1 while avoiding the quantum dots QD. Accordingly, the filaments F may be uniformly grown. The switching layer 530 on which the set operation is performed may include filaments F connected between the second surface S2 and the first surface S1 while avoiding the quantum dots QD. The filaments F may be uniformly distributed in the switching layer 530 under an electric field that concentrates filaments in areas that avoid the quantum dots QD so that the filaments F do not contact the quantum dots QD.

According to the structure described above, an electric field may be concentrated locally using the quantum dots QD. The electric field may be concentrated on the quantum dots QD or concentrated to avoid the quantum dots QD. Accordingly, the filaments F may be uniformly grown and distributed.

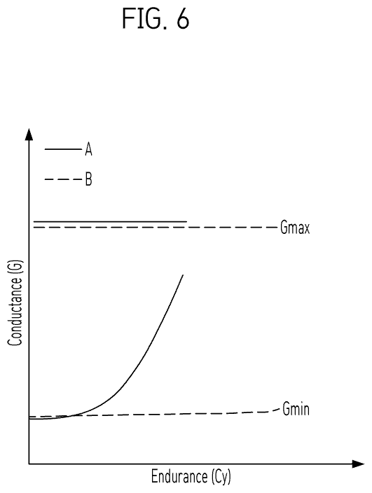

FIG. 6 is a graph illustrating characteristics of a semiconductor device in accordance with an embodiment of the disclosure. An x-axis of the graph represents the number of times a set/reset operation cycle is repeated (Endurance Cy), and a y-axis of the graph represents electrical conductance of a resistive memory cell (Conductance G).

Referring to FIG. 6, turn-on/off characteristics of a resistive memory cell A that does not include quantum dots and a resistive memory cell B that includes quantum dots may be compared. In resistive memory cells A that do not include the quantum dots, a maximum value Gmax of electrical conductance is maintained as a constant value without significant change even though the number of set/reset cycles increases, but a minimum value Gmin of the electrical conductance increases as the number of set/reset cycles increases. Thus, as the number of cycling times increases, a difference between the maximum value Gmax and the minimum value Gmin decreases. Therefore, the turn-on/off characteristics of the resistive memory cell A, which does not include the quantum dots, deteriorate as the number of times of cycling increases.

In resistive memory cells B that include the quantum dots, both a maximum value Gmax and a minimum value Gmin of electrical conductance are maintained as constant values without significant change even though the number of set/reset cycling increases. Even though the number of set/reset cycles increases, a difference between the maximum value Gmax and the minimum value Gmin is maintained. Therefore, the turn-on/off characteristics of a resistive memory cell B that includes quantum dots do not deteriorate even though the number of cycles increases. Using quantum dots in resistive memory cells improves targeting and control of filaments generated or degraded under an electric field that can be directed by quantum dot.

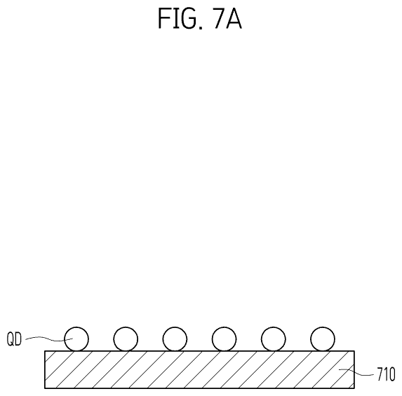

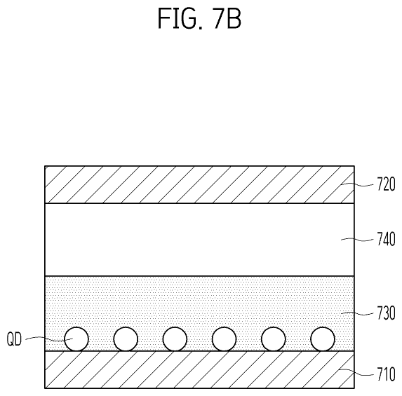

FIGS. 7A and 7B are diagrams describing a manufacturing method of a semiconductor device in accordance with an embodiment of the disclosure. Hereinafter, content that overlaps with previously described content may be omitted from the description for clarity.

Referring to FIG. 7A, a first electrode 710 may be formed. The first electrode 710 may include a conductive material such as titanium nitride (TiN). Subsequently, quantum dots QD may be formed on the first electrode 710. As an example, the quantum dots QD may each be a metal-based material. The quantum dots QD may each include titanium (Ti), gold (Au), platinum (Pt), or the like, or include noble metal. As an example, the quantum dots QD may each be an oxide-based material or a metal-based material coated with an oxide-based material. The quantum dots QD may each include an oxide-based material such as SiO₂, Al₂O₃, La₂O₃, Gd₂O₃, and ZrO₂. As an example, the quantum dots QD may each be a graphite oxide quantum dot.

The quantum dots QD may be formed by surface treatment, a deposition method, or the like. As an example, a surface of the first electrode 710 may be annealed or plasma-dewetted, and agglomeration may occur on the surface of the first electrode 710 to form the quantum dots QD having a size of several nanometers. As an example, the quantum dots QD may be formed on the surface of the first electrode 710 using a deposition method.

Referring to FIG. 7B, a switching layer 730 may be formed on the first electrode 710 on which the quantum dots QD are formed. The switching layer 730 may be formed around the quantum dots QD. The switching layer 730 may include metal oxide such as hafnium oxide (HfO₂). Subsequently, an oxygen reservoir layer 740 may be formed on the switching layer 730. The oxygen reservoir layer 740 may include metal such as tantalum (Ta) or metal oxide. Subsequently, a second electrode 720 may be formed on the oxygen reservoir layer 740.

According to the manufacturing method described above, the quantum dots QD may be formed at an interface between the first electrode 710 and the switching layer 730. Accordingly, a resistive memory cell including the quantum dots QD may be formed.

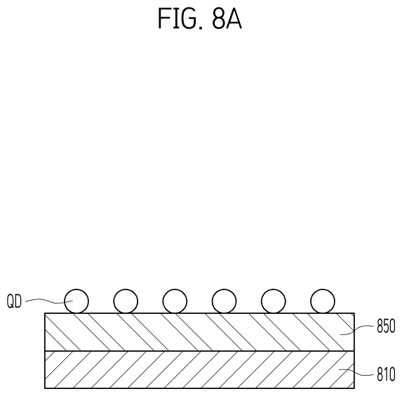

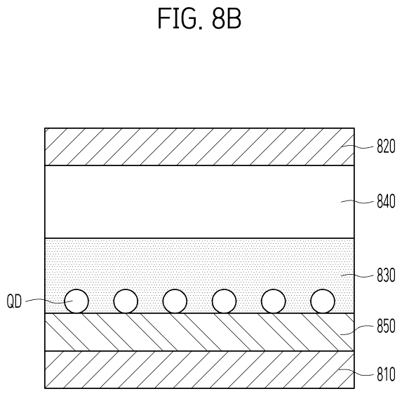

FIGS. 8A and 8B are diagrams describing a manufacturing method of a semiconductor device in accordance with an embodiment of the disclosure. Hereinafter, content that overlaps with previously described content may be omitted from the description for clarity.

Referring to FIG. 8A, a first electrode 810 may be formed. The first electrode 810 may include a conductive material such as titanium nitride (TIN). Subsequently, a seed layer 850 may be formed on the first electrode 810. The seed layer 850 may include metal such as titanium (Ti), gold (Au), or platinum (Pt), or include a two-dimensional material.

Subsequently, quantum dots QD may be formed on the seed layer 850. As an example, a surface of the seed layer 850 may be annealed or plasma-dewetted, and agglomeration may occur on the surface of the seed layer 850 to form the quantum dots QD having a size of several nanometers.

Referring to FIG. 8B, a switching layer 830 may be formed on the seed layer 850 and around the quantum dots QD. The switching layer 830 may include metal oxide such as hafnium oxide (HfO₂). Subsequently, an oxygen reservoir layer 840 may be formed on the switching layer 830. The oxygen reservoir layer 840 may include metal such as tantalum (Ta) or metal oxide. Subsequently, a second electrode 820 may be formed on the oxygen reservoir layer 840.

According to the manufacturing method described above, the quantum dots QD may be formed at an interface between the seed layer 850 and the switching layer 830. Accordingly, a resistive memory cell including quantum dots QD may be formed.

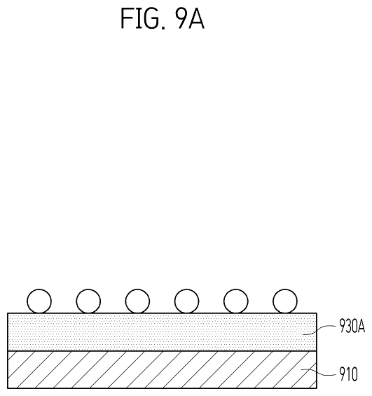

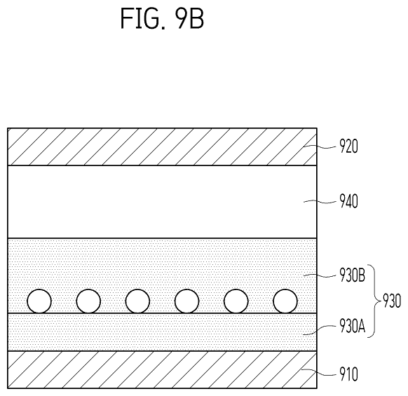

FIGS. 9A and 9B are diagrams describing a manufacturing method of a semiconductor device in accordance with an embodiment of the disclosure. Hereinafter, content that overlaps with previously described content may be omitted from the description for clarity.

Referring to FIG. 9A, a first electrode 910 may be formed. The first electrode 910 may include a conductive material such as titanium nitride (TiN). Subsequently, a first switching layer 930A may be formed on the first electrode 910. The first switching layer 930A may include metal oxide such as hafnium oxide (HfO₂). Subsequently, quantum dots QD may be formed on the first switching layer 930A. The quantum dots QD may each be a metal-based material, an oxide-based material, or a metal-based material coated with an oxide-based material. As an example, graphite oxide quantum dots may be deposited on a surface of the first switching layer 930A.

Referring to FIG. 9B, a second switching layer 930B may be formed on the first switching layer 930A on which the quantum dots QD are formed. The second switching layer 930B may be formed around the quantum dots QD. The second switching layer 930B may include metal oxide such as hafnium oxide (HfO₂). Subsequently, an oxygen reservoir layer 940 may be formed on the second switching layer 930B. The oxygen reservoir layer 940 may include metal such as tantalum (Ta) or metal oxide. Subsequently, a second electrode 920 may be formed on the oxygen reservoir layer 940.

According to the manufacturing method described above, quantum dots QD may be formed inside the switching layer 930. The quantum dots QD may be formed at an interface between the first switching layer 930A and the second switching layer 930B. Accordingly, a resistive memory cell including quantum dots QD may be formed.

Although embodiments according to the technical idea of the present disclosure have been described above with reference to the accompanying drawings, this is only for explaining embodiments according to the concepts of the present disclosure, and the present disclosure is not limited to the above embodiments. Various types of substitutions, modifications, changes, and combinations for the embodiments may be made by those skilled in the art, to which the present disclosure pertains, without departing from the technical idea of the present disclosure defined in the following claims, and it should be construed that these substitutions, modifications, changes, and combinations belong to the scope of the present disclosure.

What is claimed is:

1. A semiconductor device comprising:
a first electrode;
a switching layer on the first electrode;
an oxygen reservoir layer on the switching layer;
a second electrode on the oxygen reservoir layer; and
a quantum dot between the first electrode and the switching layer.

2. The semiconductor device of claim 1, wherein the switching layer includes a first surface common to the first electrode and a second surface common to the oxygen reservoir layer, and
wherein the quantum dot is located on the first surface.

3. The semiconductor device of claim 2, wherein the switching layer on which a set operation is performed includes a filament connecting the second surface and the quantum dot.

4. The semiconductor device of claim 3, wherein the quantum dot includes a metal-based material.

5. The semiconductor device of claim 2, wherein the switching layer on which a set operation is performed includes a filament connecting the second surface and the first surface without contacting to the quantum dot.

6. The semiconductor device of claim 5, wherein the quantum dot includes an oxide-based material.

7. The semiconductor device of claim 1, wherein the switching layer includes filaments distributed in the switching layer by an electric field concentrated on a plurality of quantum dots including the quantum dot.

8. The semiconductor device of claim 1, wherein the quantum dot is a diffusion barrier for oxygen vacancies diffusing from the first electrode to the switching layer.

9. The semiconductor device of claim 1, further comprising a seed layer located between the first electrode and the switching layer.

10. A semiconductor device comprising:
a first electrode;
a first switching layer located on the first electrode;
a second switching layer located on the first switching layer;
an oxygen reservoir layer located on the second switching layer;
a second electrode located on the oxygen reservoir layer; and
a quantum dot located between the first switching layer and the second switching layer.

11. The semiconductor device of claim 10, wherein the first switching layer includes a first surface common to the first electrode,
the second switching layer includes a second surface common to the oxygen reservoir layer, and
the quantum dot is located at an interface between the first switching layer and the second switching layer.

12. The semiconductor device of claim 11, wherein the first switching layer and the second switching layer on which a set operation is performed includes a filament connecting the second surface and the first surface through the quantum dot.

13. The semiconductor device of claim 12, wherein the quantum dot includes a metal-based material.

14. The semiconductor device of claim 11, wherein the first switching layer and the second switching layer on which a set operation is performed includes a filament connecting the second surface and the first surface without contacting to the quantum dot.

15. The semiconductor device of claim 14, wherein the quantum dot includes an oxide-based material.

16. The semiconductor device of claim 10, wherein the quantum dot is a graphite oxide quantum dot.

17. The semiconductor device of claim 10, wherein the first switching layer and the second switching layer include filaments distributed in the first and second switching layers by an electric field concentrated on a plurality of quantum dots including the quantum dot.

18. The semiconductor device of claim 10, wherein the quantum dot is a diffusion barrier for oxygen vacancies diffusing from the first electrode to the first switching layer.

19. The semiconductor device of claim 10, wherein the second switching layer has a greater thickness than the first switching layer.
